(19) United States
(12) Patent Application Publication
(10) Pub. No.: US 2025/0246573 A1
(43) Pub. Date: Jul. 31, 2025

(54) SEMICONDUCTOR PACKAGE

(71) Applicant: Samsung Electronics Co., Ltd., Suwon-si (KR)

(72) Inventors: Wonil SEO, Suwon-si (KR); Kwangyong LEE, Suwon-si (KR); Jiwon SHIN, Suwon-si (KR); Sanghyeon LEE, Suwon-si (KR)

(73) Assignee: Samsung Electronics Co., Ltd., Suwon-si (KR)

(21) Appl. No.: 19/002,303

(22) Filed: Dec. 26, 2024

(30) Foreign Application Priority Data
Jan. 31, 2024 (KR) 10-2024-0014814

(51) Int. Cl. H01L 23/00; H01L 23/29; H01L 23/31; H01L 25/03

(52) U.S. Cl. CPC H01L 24/48; H01L 23/3135; H01L 25/03; H01L 23/293; H01L 24/45; H01L 2224/45139; H01L 2224/45144; H01L 2224/45147; H01L 2224/4805; H01L 2224/48227

(57) ABSTRACT

A semiconductor package includes a package substrate including substrate pads on an upper portion of the package substrate, a first semiconductor chip on the package substrate, a first chip pad on the first semiconductor chip, a first conductive connection pattern on an upper surface of the first chip pad, an upper surface of the first semiconductor chip, and an upper surface of a first substrate pad among the substrate pads, and a first insulation layer on the package substrate and covering the first semiconductor chip, the first chip pad and the first conductive connection pattern.

### CROSS-REFERENCE TO RELATED APPLICATION

This application claims priority under 35 U.S.C. § 119 to Korean Patent Application No. 10-2024-0014814, filed on Jan. 31, 2024 in the Korean Intellectual Property Office (KIPO), the contents of which are herein incorporated by reference in their entirety.

### BACKGROUND

Some example embodiments relate to semiconductor packages. More particularly, example embodiments relate to semiconductor packages including a plurality of chips stacked on a package substrate.

In a multi-chip package including a plurality of semiconductor chips stacked on a package substrate, chip pads in the semiconductor chips and substrate pads in the package substrate may be electrically connected to each other by bonding wires. The bonding wires need a large space horizontally and vertically, and thus, a volume of the multi-chip package may increase.

### SUMMARY

Some example embodiments provide semiconductor packages having enhanced electrical characteristics.

According to some example embodiments, there is provided a semiconductor package. The semiconductor package may include a package substrate including substrate pads on an upper portion of the package substrate, a first semiconductor chip on the package substrate, a first chip pad on the first semiconductor chip, a first conductive connection pattern on an upper surface of the first chip pad, an upper surface of the first semiconductor chip, and an upper surface of a first substrate pad among the substrate pads, and a first insulation layer on the package substrate and covering the first semiconductor chip, the first chip pad and the first conductive connection pattern.

According to some example embodiments, there is provided a semiconductor package. The semiconductor package may include a package substrate including substrate pads on an upper portion of the package substrate, semiconductor chips stacked on the package substrate, chip pads on each of the semiconductor chips, respectively, and a conductive connection pattern on an upper surface of each of the chip pads, a sidewall of a corresponding one of the semiconductor chips, and a respective one of the substrate pads.

According to some example embodiments, there is provided a semiconductor package. The semiconductor package may include a package substrate including first, second and third substrate pads on an upper portion of the package substrate, a first semiconductor chip on the package substrate, a first chip pad on the first semiconductor chip, a first chip protective layer on the first semiconductor chip and covering a sidewall of the first chip pad, a first conductive connection pattern on an upper surface of the first chip pad, an upper surface and a sidewall of the first chip protective layer, a sidewall of the first semiconductor chip and an upper surface of a first substrate pad, a first insulation layer on the package substrate and covering the first semiconductor chip, the first chip pad and the first conductive connection pattern, a second semiconductor chip on the first insulation layer, a second chip pad on the second semiconductor chip, a second chip protective layer on the second semiconductor chip and covering a sidewall of the second chip pad, a second conductive connection pattern on an upper surface of the second chip pad, an upper surface and a sidewall of the second chip protective layer, a sidewall of the second semiconductor chip and an upper surface of a second substrate pad, a second insulation layer on the package substrate and covering the first insulation layer, the second semiconductor chip, the second chip pad and the second conductive connection pattern, a third semiconductor chip on the second insulation layer, a third chip pad on the third semiconductor chip, a third chip protective layer on the third semiconductor chip and covering a sidewall of the third chip pad, a third conductive connection pattern on an upper surface of the third chip pad, an upper surface and a sidewall of the third chip protective layer, a sidewall of the third semiconductor chip and an upper surface of a third substrate pad, and a molding member on the package substrate and covering the second insulation layer, the third semiconductor chip, the third chip pad, the third chip protective layer and the third conductive connection pattern.

In semiconductor packages in accordance with some example embodiments, the semiconductor chips stacked on the package substrate may be electrically connected to the package substrate not through bonding wires but through the conductive connection patterns on the sidewalls and the upper surfaces of the semiconductor chips. Thus, the space for forming the bonding wires may be saved, and the speed of transferring electrical signals between the each of the semiconductor chips and the package substrate may be enhanced.

### BRIEF DESCRIPTION OF THE DRAWINGS

FIG. 1 is a cross-sectional view illustrating a semiconductor package, in accordance with some example embodiments.

FIGS. 2 to 5 are cross-sectional views illustrating methods of manufacturing semiconductor packages, in accordance with some example embodiments.

FIG. 6 is a cross-sectional view illustrating a semiconductor package, in accordance with some example embodiments.

FIG. 7 is a cross-sectional view illustrating a semiconductor package, in accordance with some example embodiments.

FIG. 8 is a cross-sectional view illustrating methods of manufacturing a semiconductor package, in accordance with some example embodiments.

### DETAILED DESCRIPTION

Hereinafter, some example embodiments will be explained in detail with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Hereinafter, a direction that is substantially parallel to an upper surface of a wafer, a substrate or a chip may be referred to as a horizontal direction, and a direction that is substantially perpendicular to the upper surface of the wafer, the substrate or the chip may be referred to as a vertical direction.

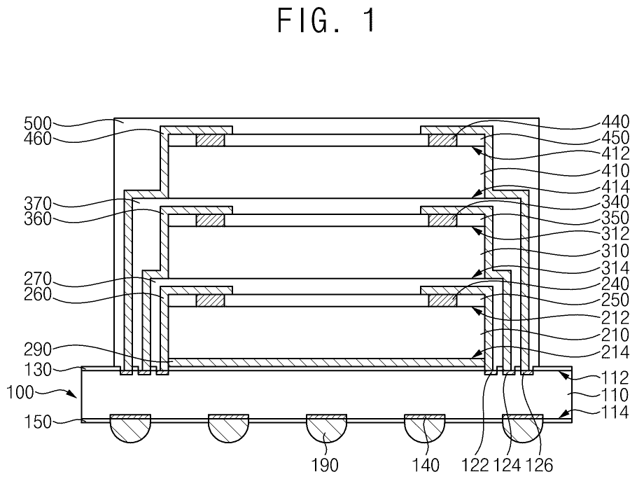

FIG. 1 is a cross-sectional view illustrating a semiconductor package, in accordance with some example embodiments.

Referring to FIG. 1, the semiconductor package may include a package substrate structure 100, first to third semiconductor chips 210, 310 and 410 sequentially stacked on the package substrate structure 100 in the vertical direction, and a molding member 500.

The semiconductor package may further include first to third conductive connection patterns 260, 360 and 460, first and second insulation layers 270 and 370, first to third chip pads 240, 340 and 440, first to third chip protective layers 250, 350 and 450, first adhesion layer 290 and an outer connection member 190.

In some example embodiments, the semiconductor package may be a multi-chip package including the same kind of semiconductor chips or different kinds of semiconductor chips. Alternatively, the semiconductor package may be a system in package (SIP) including a plurality of semiconductor chips that are stacked or arranged in a package and having an independent function.

The first to third semiconductor chips 210, 310 and 410 in the semiconductor package may be the same kind of chips and have the same structure and size, however, the inventive concepts may not be limited thereto. Additionally, the semiconductor package may include three semiconductor chips sequentially stacked in the vertical direction on the package substrate structure 100, however, the inventive concepts may not be limited thereto, and more or less than three semiconductor chips may be stacked in the semiconductor package.

The package substrate structure 100 may include a package substrate 110 having first and second surfaces 112 and 114 opposite to each other in the vertical direction, a first substrate protective layer 130 on the first surface 112 of the package substrate 110, and a second substrate protective layer 150 beneath the second surface 114 of the package substrate 110.

The package substrate 110 may be, e.g., a printed circuit board (PCB), which may be a multi-layer circuit board having various circuit patterns, e.g., transistors, wirings, vias, contact plugs, conductive pads, etc.

In some example embodiments, the circuit patterns may include first to third substrate pads 122, 124 and 126 at a portion of the package substrate 110 adjacent to the first surface 112 thereof, and a fourth substrate pad 140 at a portion of the package substrate 110 adjacent to the second surface 114 thereof. For example, the first to third substrate pads 122, 124, and 126 may not be covered by the first substrate protective layer 130 but may be exposed by the first substrate protective layer 130. In some example embodiments, the fourth substrate pad 140 may not be covered by the second substrate protective layer 150 and may be exposed by the second substrate protective layer 150. The first to third substrate pads 122, 124 and 126 may be closer, in a horizontal direction, to a central portion of the package substrate 110 in this order.

Each of the first to third substrate pads 122, 124 and 126 may transfer electrical signals to semiconductor chips that may be stacked on the package substrate structure 100, and may serve as a bonding pad such as a bonding finger. The fourth substrate pad 140 may transfer electrical signals to a module substrate that may be disposed under the package substrate structure 100, and may serve as an outer connection pad.

The outer connection member 190 may contact a lower surface of the fourth substrate pad 140, and a lower portion of the outer connection member 190 may be covered by the second substrate protective layer 150.

Each of the first to fourth substrate pads 122, 124, 126 and 140 may include a metal, e.g., copper, aluminum, nickel, etc., and the outer connection member 190 may include, e.g., solder that is an alloy of tin, silver, copper, lead, etc. Each of the first and second substrate protective layers 130 and 150 may include an oxide, e.g., silicon oxide or an insulating nitride, e.g., silicon nitride.

The first semiconductor chip 210 may include first and second surfaces 212 and 214 opposite to each other in the vertical direction.

The first semiconductor chip 210 may include a first substrate, and a circuit device and a first wiring structure on the first substrate.

The first substrate may include a semiconductor material, e.g., silicon, germanium, silicon-germanium, etc., or a III-V group compound semiconductor, e.g., GaP, GaAs, GaSb, etc. In some example embodiments, the first substrate may be a silicon-on-insulator (SOI) substrate or a germanium-on-insulator (GOI) substrate.

The circuit device may include, e.g., a logic device or a memory device. The memory device may include a volatile memory device such as a DRAM device, an SRAM device, etc., or a non-volatile memory device such as a flash memory device, an EEPROM device, etc.

The first wiring structure may include, e.g., wirings, vias, contact plugs, etc., which may be covered by a first insulating interlayer.

The first insulating interlayer may include an oxide, e.g., silicon oxide, an insulating nitride, e.g., silicon nitride, and/or a low-k dielectric material. The wirings, the vias and the contact plugs may include, e.g., a metal, a metal nitride, and/or a metal silicide, etc.

The first chip pad 240 may be disposed on the first surface 212 of the first semiconductor chip 210, and may be electrically connected to the first wiring structure. A sidewall of the first chip pad 240 may be covered by the first chip protective layer 250 on the first surface 212 of the first semiconductor chip 210.

In some example embodiments, a plurality of first chip pads 240 may be spaced apart from each other at an edge portion of the first semiconductor chip 210.

The first chip pad 240 may include, e.g., a metal, a metal nitride, and/or a metal silicide, etc., and the first chip protective layer 250 may include, e.g., an oxide such as silicon oxide, an insulating nitride such as silicon nitride, and/or a low-k dielectric material.

In some example embodiments, the first semiconductor chip 210 may be bonded with an upper surface of the first substrate protective layer 130 of the package substrate structure 100 through the first adhesion layer 290 beneath the second surface 214 of the first semiconductor chip 210. The first adhesion layer 290 may include an adhesive material, e.g., die attach film (DAF).

The first conductive connection pattern 260 may be electrically connected to the first chip pad 240 in the first semiconductor chip 210 and the first substrate pad 122 in the package substrate structure 100.

In example embodiments, the first conductive connection pattern 260 may contact an upper surface of the first chip pad 240, an upper surface and a sidewall of an edge portion of the first chip protective layer 250, a sidewall of the first semiconductor chip 210, a sidewall of the first adhesion layer 290, and an upper surface of the first substrate pad 122. The first conductive connection pattern 260 may have a shape of a line extending in the horizontal direction on the upper surface of the edge portion of the first chip protective layer 250 and the upper surface of the first chip pad 240, and a shape of a line extending in the vertical direction on the sidewall of the edge portion of the first chip protective layer 250, the sidewall of the first semiconductor chip 210 and the sidewall of the first adhesion layer 290. The first conductive connection pattern 260 may be bent at an interface between the upper surface and the sidewall of the edge portion of the first chip protective layer 250. For example, the first conductive connection pattern 260 may follow the contours of the side and upper surfaces of the first adhesion layer 290, the semiconductor chip 210, the first protective layer 250, and the first chip pad 240.

In some example embodiments, a plurality of first conductive connection patterns 260 may be spaced apart from each other in the horizontal direction, and each of the first conductive connection patterns 260 may contact the first chip pad 240 and the first substrate pad 122 to be electrically connected thereto.

FIG. 1 shows that the first conductive connection pattern 260 contacts only a portion of an upper surface of the first substrate pad 122, however, the inventive concepts may not be limited thereto, and may contact an entire portion of the upper surface of the first substrate pad 122.

The first conductive connection pattern 260 may include a metal, e.g., gold, silver, copper, etc., a metal nitride, and/or a metal silicide, etc.

The first insulation layer 270 may be disposed on the package substrate structure 100, and may cover the first semiconductor chip 210, the first chip pad 240, the first chip protective layer 250 and the first conductive connection pattern 260.

In some example embodiments, the first insulation layer 270 may cover an upper surface of a portion of the first substrate pad 122 in the package substrate structure 100 and an upper surface of a portion of the first substrate protective layer 130 adjacent thereto. However, the inventive concepts may not be limited thereto, and if the first conductive connection pattern 260 covers an entire portion of the upper surface of the first substrate pad 122, the first insulation layer 270 may cover an upper surface of only a portion of the first substrate protective layer 130 adjacent to the first substrate pad 122.

In some example embodiments, the first insulation layer 270 may include, e.g., epoxy or a thermosetting resin such as a polymer or an inorganic insulation material.

Each of the second and third semiconductor chips 310 and 410 may have a structure substantially the same as or similar to that of the first semiconductor chip 210, and thus repeated explanations are omitted herein.

The second semiconductor chip 310 may include first and second surfaces 312 and 314 opposite to each other in the vertical direction.

The second semiconductor chip 310 may include a second substrate, and a circuit device and a second wiring structure on the second substrate. The second wiring structure may include, e.g., wirings, vias, contact plugs, etc., which may be covered by a second insulation interlayer 370.

The second chip pad 340 may be disposed on the first surface 312 of the second semiconductor chip 310, and may be electrically connected to the second wiring structure. A sidewall of the second chip pad 340 may be covered by the second chip protective layer 350 on the first surface 312 of the second semiconductor chip 310.

In some example embodiments, a plurality of second chip pads 340 may be spaced apart from each other at an edge portion of the second semiconductor chip 310.

In some example embodiments, the second surface 314 of the second semiconductor chip 310 may be bonded with an upper surface of the first insulation layer 270 on the first semiconductor chip 210, particularly, an upper surface of a central portion of the first insulation layer 270 in a plan view.

The second conductive connection pattern 360 may be electrically connected to the second chip pad 340 in the second semiconductor chip 310 and the second substrate pad 124 in the package substrate structure 100.

In some example embodiments, the second conductive connection pattern 360 may contact an upper surface of the second chip pad 340, an upper surface and a sidewall of an edge portion of the second chip protective layer 350, a sidewall of the second semiconductor chip 310, and upper surface and a sidewall of an edge portion of the first insulation layer 270, and an upper surface of the second substrate pad 124. The second conductive connection pattern 360 may have a shape of a line extending in the horizontal direction on the upper surface of the edge portion of the second chip protective layer 350 and the upper surface of the second chip pad 340, a shape of a line extending in the vertical direction on the sidewall of the edge portion of the second chip protective layer 350 and the sidewall of the second semiconductor chip 310, a shape of a line extending in the horizontal direction on the upper surface of the edge portion of the first insulation layer 270, and a shape of a line extending in the vertical direction on the sidewall of the first insulation layer 270.

Thus, the second conductive connection pattern 360 may be bent at an interface between the upper surface and the sidewall of the edge portion of the second chip protective layer 350, at an interface between the sidewall of the second semiconductor chip 310 and the upper surface of the edge portion of the first insulation layer 270, and at an interface between the upper surface and the sidewall of the edge portion of the first insulation layer 270. For example, the second conductive connection pattern 360 may follow the contours of side and upper surfaces of first insulation layer 270, the second semiconductor chip 310, the second chip protective layer 350, and the second chip pad 340. For example, the second conductive connection pattern 360 may form a step (e.g., a horizontal portion between two vertical portions at opposite ends of the horizontal portion) on the first insulation layer 270.

In some example embodiments, a plurality of second conductive connection patterns 360 may be spaced apart from each other in the horizontal direction, and each of the second conductive connection patterns 360 may contact the second chip pad 340 and the second substrate pad 124 to be electrically connected thereto.

FIG. 1 shows that the second conductive connection pattern 360 contacts only a portion of an upper surface of the second substrate pad 124, however, the inventive concepts may not be limited thereto, and may contact an entire portion of the upper surface of the second substrate pad 124.

The second insulation layer 370 may be disposed on the package substrate structure 100, and may cover the first insulation layer 270, the second semiconductor chip 310, the second chip pad 340, the second chip protective layer 350 and the second conductive connection pattern 360.

In some example embodiments, the second insulation layer 370 may cover an upper surface of a portion of the second substrate pad 124 in the package substrate structure 100 and an upper surface of a portion of the first substrate protective layer 130 adjacent thereto. However, the inventive concepts may not be limited thereto, and if the second conductive connection pattern 360 covers an entire portion of the upper surface of the second substrate pad 124, the second insulation layer 370 may cover an upper surface of only a portion of the first substrate protective layer 130 adjacent to the second substrate pad 124.

In some example embodiments, the second insulation layer 370 may include, e.g., epoxy or a thermosetting resin such as a polymer or an inorganic insulation material.

The third semiconductor chip 410 may include first and second surfaces 412 and 414 opposite to each other in the vertical direction.

The third semiconductor chip 410 may include a third substrate, and a circuit device and a third wiring structure on the third substrate. The third wiring structure may include, e.g., wirings, vias, contact plugs, etc., which may be covered by a third insulating interlayer.

The third chip pad 440 may be disposed on the first surface 412 of the third semiconductor chip 410, and may be electrically connected to the third wiring structure. A sidewall of the third chip pad 440 may be covered by the third chip protective layer 450 on the first surface 412 of the third semiconductor chip 410.

In some example embodiments, a plurality of third chip pads 440 may be spaced apart from each other at an edge portion of the third semiconductor chip 410.

In some example embodiments, the second surface 414 of the third semiconductor chip 410 may be bonded with an upper surface of the second insulation layer 370 on the second semiconductor chip 310, particularly, an upper surface of a central portion of the second insulation layer 370 in a plan view.

The third conductive connection pattern 460 may be electrically connected to the third chip pad 440 in the third semiconductor chip 410 and the third substrate pad 126 in the package substrate structure 100.

In some example embodiments, the third conductive connection pattern 460 may contact an upper surface of the third chip pad 440, an upper surface and a sidewall of an edge portion of the third chip protective layer 450, a sidewall of the third semiconductor chip 410, an upper surface and a sidewall of an edge portion of the second insulation layer 370, and an upper surface of the third substrate pad 126. The third conductive connection pattern 460 may have a shape of a line extending in the horizontal direction on the upper surface of the edge portion of the third chip protective layer 450 and the upper surface of the third chip pad 440, a shape of a line extending in the vertical direction on the sidewall of the edge portion of the third chip protective layer 450 and the sidewall of the third semiconductor chip 410, a shape of a line extending in the horizontal direction on the upper surface of the edge portion of the second insulation layer 370, and a shape of a line extending in the vertical direction on the sidewall of the second insulation layer 370.

Thus, the third conductive connection pattern 460 may be bent at an interface between the upper surface and the sidewall of the edge portion of the third chip protective layer 450, at an interface between the sidewall of the third semiconductor chip 410 and the upper surface of the edge portion of the second insulation layer 370, and at an interface between the upper surface and the sidewall of the edge portion of the second insulation layer 370. For example, the third conductive connection pattern 460 may follow the contours of side and upper surfaces of second insulation layer 370, the third semiconductor chip 410, the third chip protective layer 450, and the third chip pad 440. For example, the third conductive connection pattern 460 may form a step (e.g., a horizontal portion between two vertical portions at opposite ends of the horizontal portion) on the second insulation layer 370.

In some example embodiments, a plurality of third conductive connection patterns 460 may be spaced apart from each other in the horizontal direction, and each of the third conductive connection patterns 460 may contact the third chip pad 440 and the third substrate pad 126 to be electrically connected thereto.

FIG. 1 shows that the third conductive connection pattern 460 contacts only a portion of an upper surface of the third substrate pad 126, however, the inventive concepts may not be limited thereto, and may contact an entire portion of the upper surface of the third substrate pad 126.

The molding member 500 may be disposed on the package substrate structure 100, and may cover the second insulation layer 370, the third semiconductor chip 410, the third chip pad 440, the third chip protective layer 450 and the third conductive connection pattern 460.

In some example embodiments, the molding member 500 may cover an upper surface of a portion of the third substrate pad 126 in the package substrate structure 100 and an upper surface of a portion of the first substrate protective layer 130 adjacent thereto. However, the inventive concepts may not be limited thereto, and if the third conductive connection pattern 460 covers an upper surface of an entire portion of the third substrate pad 126, the molding member 500 may cover an upper surface of only a portion of the first substrate protective layer 130 adjacent thereto.

The molding member 500 may include, e.g., epoxy molding compound (EMC).

The first to third semiconductor chips 210, 310 and 410 in the semiconductor package may be electrically connected to the package substrate structure 100 through the first to third conductive connection patterns 260, 360 and 460, respectively, which may be disposed on the sidewalls of the first to third semiconductor chips 210, 310 and 410, respectively, and on the upper surfaces of the first to third chip protective layers 250, 350 and 450, respectively, instead of, e.g., bonding wires. Thus, a space, e.g., a vertical space and a horizontal space for the bonding wires is not needed, and the speed of transferring electrical signals between each of the first to third semiconductor chips 210, 310 and 410 and the package substrate structure 100 may be enhanced.

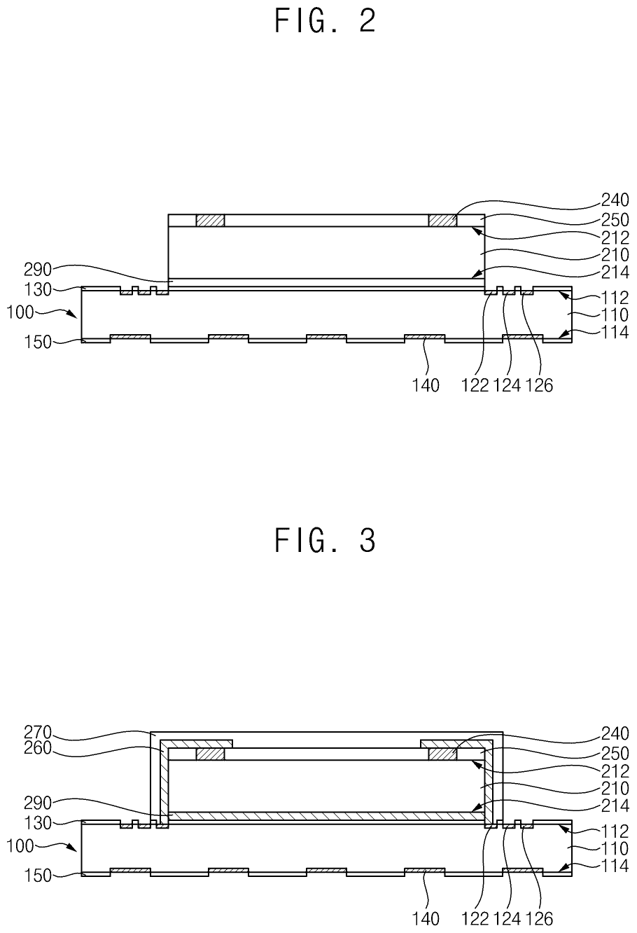

FIGS. 2 to 5 are cross-sectional views illustrating a method of manufacturing a semiconductor package in accordance with example embodiments.

Referring to FIG. 2, a first semiconductor chip 210 may be disposed on a package substrate structure 100.

In some example embodiments, the package substrate structure 100 may include a package substrate 110 having first and second surfaces 112 and 114 opposite to each other in the vertical direction. Additionally, the package substrate structure 100 may include a first substrate protective layer 130 on the first surface 112 of the package substrate 110, and a second substrate protective layer 150 beneath the second surface 114 of the package substrate 110.

The package substrate 110 may be, e.g., a printed circuit board (PCB), which may be a multi-layer circuit board having various circuit patterns. In some example embodiments, the circuit patterns may include first to third substrate pads 122, 124 and 126 adjacent to the first surface 112 of the package substrate 110, and a fourth substrate pad 140 adjacent to the second surface 114 of the package substrate 110.

The first semiconductor chip 210 may include first and second surfaces 212 and 214 opposite to each other in the vertical direction. A first chip pad 240 may be disposed on the first surface 212 of the first semiconductor chip 210, and may be electrically connected to a first wiring structure in the first semiconductor chip 210, and a sidewall of the first chip pad 240 may be covered by a first chip protective layer 250 on the first surface 212 of the first semiconductor chip 210.

The first semiconductor chip 210 may be bonded with the first substrate protective layer 130 of the package substrate structure 100 through a first adhesion layer 290 beneath the second surface 214.

Referring to FIG. 3, a first conductive connection pattern 260 may be formed to be electrically connected to the first chip pad 240 on the first semiconductor chip 210 and the first substrate pad 122 of the package substrate structure 100.

In example embodiments, the first conductive connection pattern 260 may contact an upper surface of the first chip pad 240, an upper surface and a sidewall of an edge portion of the first chip protective layer 250, a sidewall of the first semiconductor chip 210 and an upper surface of the first substrate pad 122.

In some example embodiments, the first conductive connection pattern 260 may be formed by a dispensing process. Alternatively, the first conductive connection pattern 260 may be formed by performing a deposition process to form a first conductive connection layer and performing an etching process to pattern the first conductive connection layer.

A first insulation layer 270 may be formed on the package substrate structure 100 to cover the first semiconductor chip 210, the first chip pad 240, the first chip protective layer 250 and the first conductive connection pattern 260.

In some example embodiments, the first insulation layer 270 may cover an upper surface of a portion of the first substrate pad 122 of the package substrate structure 100 and an upper surface of a portion of the first substrate protective layer 130 adjacent to the portion of the first substrate pad 122.

In some example embodiments, the first insulation layer 270 may include epoxy or a thermosetting resin such as a polymer or an inorganic insulation material, and may be formed by, e.g., a dispensing process.

Referring to FIG. 4, processes substantially the same as or similar to those illustrated with respect to FIGS. 2 to 3 may be performed so that a second semiconductor chip 310 may be stacked on the first semiconductor chip 210 and a second conductive connection pattern 360 and a second insulation layer 370 may be formed on the package substrate structure 100.

The second semiconductor chip 310 may include first and second surfaces 312 and 314 opposite to each other in the vertical direction. A second chip pad 340 may be disposed on the first surface 312 of the second semiconductor chip 310, and may be electrically connected to a second wiring structure in the second semiconductor chip 310. A sidewall of the second chip pad 340 may be covered by a second chip protective layer 350 on the first surface 312 of the second semiconductor chip 310.

In some example embodiments, the second surface 314 of the second semiconductor chip 310 may contact an upper surface of the first insulation layer 270 on the first semiconductor chip 210, particularly, an upper surface of a central portion of the first insulation layer 270 in a plan view.

The second conductive connection pattern 360 may be electrically connected to the second chip pad 340 on the second semiconductor chip 310 and the second substrate pad 124 of the package substrate structure 100.

In some example embodiments, the second conductive connection pattern 360 may contact an upper surface of the second chip pad 340, an upper surface and a sidewall of an edge portion of the second chip protective layer 350, a sidewall of the second semiconductor chip 310, an upper surface and a sidewall of the first insulation layer 270, and an upper surface of the second substrate pad 124.

In some example embodiments, the second conductive connection pattern 360 may be formed by a dispensing process. Alternatively, the second conductive connection pattern 360 may be formed by performing a deposition process to form a second conductive connection layer and performing an etching process to pattern the second conductive connection layer.

The second insulation layer 370 may be formed on the package substrate structure 100, and may cover the first insulation layer 270, the second semiconductor chip 310, the second chip pad 340, the second chip protective layer 350 and the second conductive connection pattern 360.

In some example embodiments, the second insulation layer 370 may cover an upper surface of a portion of the second substrate pad 124 of the package substrate structure 100 and an upper surface of a portion of the first substrate protective layer 130 adjacent to the portion of the second substrate pad 124.

In some example embodiments, the second insulation layer 370 may include a thermosetting resin such as polymer or an inorganic insulating material, and may be formed by a dispensing process.

Referring to FIG. 5, processes substantially the same as or similar to those illustrated with respect to FIG. 4 may be performed so that a third semiconductor chip 410 may be stacked on the second semiconductor chip 310 and a third conductive connection pattern 460 may be formed on the package substrate structure 100.

The third semiconductor chip 410 may include first and second surfaces 412 and 414 opposite to each other in the vertical direction. A third chip pad 440 may be disposed on the first surface 412 of the third semiconductor chip 410, and may be electrically connected to a third wiring structure in the third semiconductor chip 410. A sidewall of the third chip pad 440 may be covered by a third chip protective layer 450 on the first surface 412 of the third semiconductor chip 410.

In some example embodiments, the second surface 414 of the third semiconductor chip 410 may contact an upper surface of the second insulation layer 370 on the second semiconductor chip 310, particularly, an upper surface of a central portion of the second insulation layer 370 in a plan view.

The third conductive connection pattern 460 may be electrically connected to the third chip pad 440 on the third semiconductor chip 410 and the third substrate pad 126 of the package substrate structure 100.

In some example embodiments, the third conductive connection pattern 460 may contact an upper surface of the third chip pad 440, an upper surface and a sidewall of an edge portion of the third chip protective layer 450, a sidewall of the third semiconductor chip 410, an upper surface and a sidewall of the second insulation layer 370, and an upper surface of the third substrate pad 126.

In some example embodiments, the third conductive connection pattern 460 may be formed by a dispensing process. Alternatively, the third conductive connection pattern 460 may be formed by performing a deposition process to form a third conductive connection layer and performing an etching process to pattern the third conductive connection layer.

A curing process may be performed on the first and second insulation layers 270 and 370 so that the second semiconductor chip 310 and the first insulation layer 270 may be bonded with each other, and the third semiconductor chip 410 and the second insulation layer 370 may be bonded with each other.

A molding member 500 may be formed on the package substrate structure 100 to cover the second insulation layer 370, the third semiconductor chip 410, the third chip pad 440, the third chip protective layer 450 and the third conductive connection pattern 460.

In some example embodiments, the molding member 500 may cover an upper surface of a portion of the third substrate pad 126 of the package substrate structure 100 and an upper surface of a portion of the first substrate protective layer 130 adjacent to the portion of the third substrate pad 126.

Referring to FIG. 1 again, an outer connection member 190 may be formed on the second surface 114 of the package substrate 110 to contact the fourth substrate pad 140, so that the semiconductor package may be manufactured.

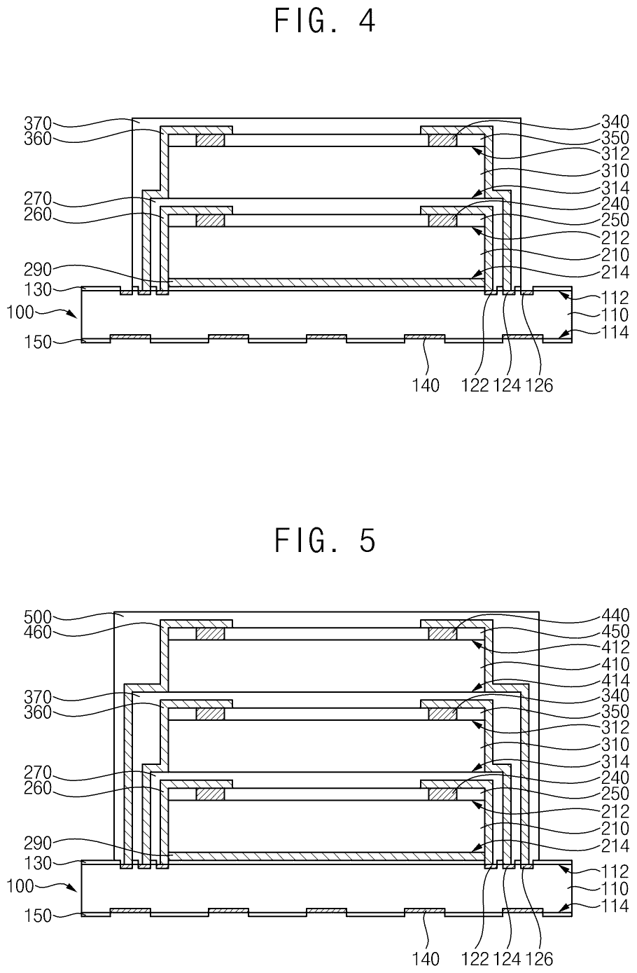

FIG. 6 is a cross-sectional view illustrating a semiconductor package in accordance with some example embodiments. This semiconductor package may be substantially the same as or similar to that of FIG. 1, except for further including second and third adhesion layers beneath lower surfaces of the second and third semiconductor chips, respectively, and thus repeated explanations are omitted herein.

Referring to FIG. 6, a second adhesion layer 390 may be interposed between the lower surface and of the second semiconductor chip 310 and the upper surface of the first insulation layer 270 so that the second semiconductor chip 310 and the first insulation layer 270 may be bonded with each other.

Additionally, a third adhesion layer 490 may be interposed between the lower surface and of the third semiconductor chip 410 and the upper surface of the second insulation layer 370 so that the third semiconductor chip 410 and the second insulation layer 370 may be bonded with each other.

Each of the second and third adhesion layers 390 and 490 may include an adhesive material, e.g., die attach film (DAF).

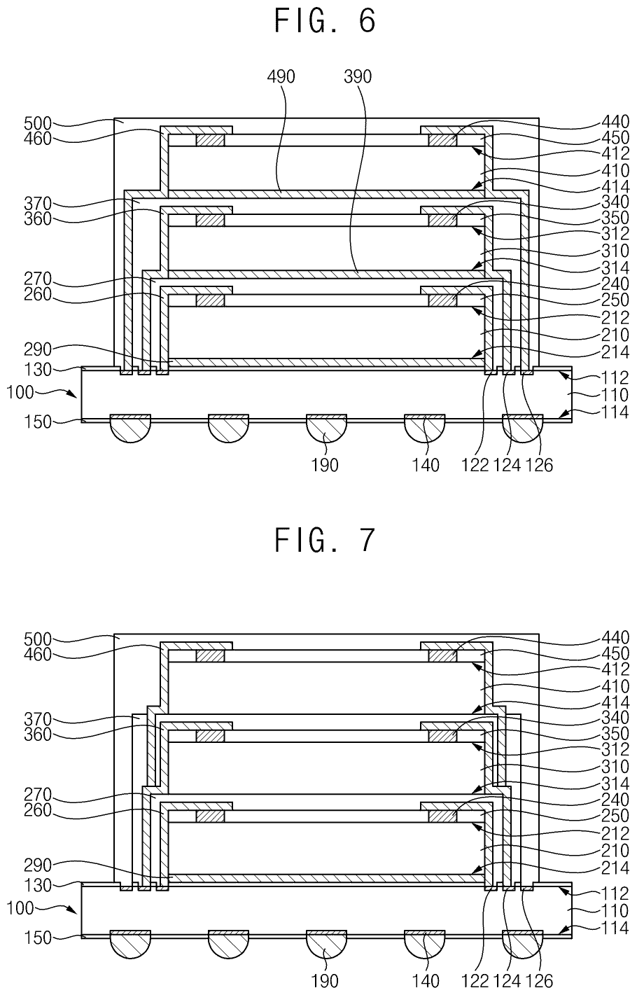

FIG. 7 is a cross-sectional view illustrating a semiconductor package in accordance with some example embodiments. This semiconductor package may be substantially the same as or similar to that of FIG. 1, except for the shape of the third conductive connection pattern, and thus repeated explanations are omitted herein.

Referring to FIG. 7, the third conductive connection pattern 460 may be disposed on the upper surface of the third chip pad 440, the upper surface and the sidewall of the edge portion of the third chip protective layer 450, the sidewall of the third semiconductor chip 410 and the upper surface of the edge portion of the second insulation layer 370.

Additionally, the third conductive connection pattern 460 may extend through the an upper portion of the edge portion of the second insulation layer 370, and may contact an upper surface of the second conductive connection pattern 360.

The third conductive connection pattern 460 may have a shape of a line extending in the horizontal direction on the upper surface of the third chip pad 440 and the upper surface of the edge portion of the third chip protective layer 450, a shape of a line extending in the vertical direction on the sidewall of the edge portion of the third chip protective layer 450 and the sidewall of the third semiconductor chip 410, a shape of a line extending in the horizontal direction on the upper surface of the edge portion of the second insulation layer 370, and a shape of a line extending in the vertical direction through the upper portion of the edge portion of the second insulation layer 370.

Thus, the third conductive connection pattern 460 may be bent at an interface between the upper surface and the sidewall of the third chip protective layer 450, at an interface between the sidewall of the third semiconductor chip 410 and the upper surface of the edge portion of the second insulation layer 370, and at an interface between the upper surface of the edge portion of the second insulation layer 370 and a sidewall of the edge portion of the second insulation layer 370.

FIG. 7 shows that an uppermost one of the first to third conductive connection patterns 260, 360 and 460, that is, the third conductive connection pattern 460 extends partially through the second insulation layer 370 to contact a portion of the second conductive connection pattern 360. However, the inventive concepts may not be limited thereto.

For example, the semiconductor package may include more than three semiconductor chips and conductive connection patterns on upper surfaces and sidewalls of the semiconductor chips, respectively. In this case, a conductive connection pattern on an upper surface of a chip pad and an upper surface and a sidewall of a chip protective layer on an upper one of the semiconductor chips may extend partially through an insulation layer covering a lower one of the semiconductor chips, and may contact a conductive connection pattern on an upper surface of a chip pad and an upper surface and a sidewall of a chip protective layer on the lower one of the semiconductor chips to be electrically thereto.

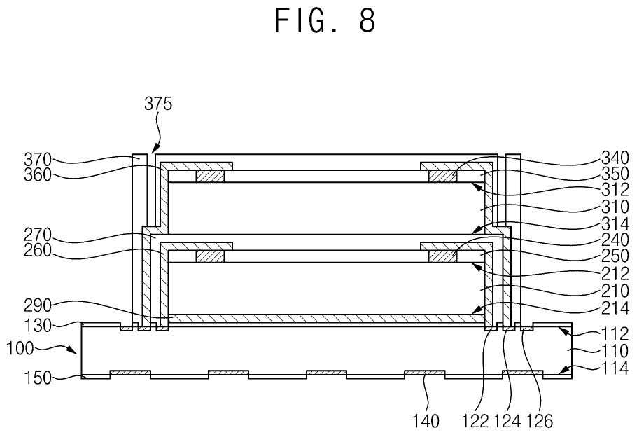

FIG. 8 is a cross-sectional view illustrating a method of manufacturing a semiconductor package in accordance with example embodiments. This method may include processes substantially the same as or similar to those illustrated with respect to FIGS. 2 to 5 and FIG. 1, and thus repeated explanations thereof are omitted herein.

Referring to FIG. 8, processes substantially the same as or similar to those illustrated with respect to FIGS. 2 to 4 may be performed so that the first semiconductor chip 210, the first chip pad 240, the first chip pad protective layer 250, the second semiconductor chip 310, the second chip pad 340 and the second chip protective layer 350 may be stacked on the package substrate structure 100, and the first and second conductive connection patterns 260 and 360 and the first and second insulation layers 270 and 370 may be formed.

The second insulation layer 370 may be partially removed to form a hole 375 exposing an upper surface of a portion of the second conductive connection pattern 360.

In example embodiments, the hole 375 may expose an upper surface of a portion of the second conductive connection pattern 360 on the first insulation layer 270.

Referring to FIG. 7 again, processes substantially the same as or similar to those illustrated with respect to FIG. 5 may be performed so that the third semiconductor chip 410, the third chip pad 440 and the third chip protective layer 450 may be stacked on the second insulation layer 370, and the third conductive connection pattern 460 may be formed on the package substrate structure 100.

In some example embodiments, the third conductive connection pattern 460 may be formed on the upper surface of the third chip pad 440, the upper surface and the sidewall of the edge portion of the third chip protective layer 450, the upper surface of a portion of the second insulation layer 370, and an upper surface of the portion of the second conductive connection pattern 360 exposed by the hole 375, and may fill the hole 375.

The molding member 500 and the outer connection member 190 may be formed to complete the manufacturing of the semiconductor package.

The foregoing is illustrative of some example embodiments and is not to be construed as limiting thereof. Although a few example embodiments have been described, those skilled in the art will readily appreciate that many modifications are possible in example embodiments without materially departing from the novel teachings and advantages of the present inventive concepts. Accordingly, all such modifications are intended to be included within the scope of example embodiments as defined in the claims.

What is claimed is:

1. A semiconductor package comprising:
a package substrate including substrate pads on an upper portion of the package substrate;
a first semiconductor chip on the package substrate;
a first chip pad on the first semiconductor chip;
a first conductive connection pattern on an upper surface of the first chip pad, an upper surface of the first semiconductor chip, and an upper surface of a first substrate pad among the substrate pads; and
a first insulation layer on the package substrate, the first insulation layer covering the first semiconductor chip, the first chip pad and the first conductive connection pattern.

2. The semiconductor package according to claim 1, further comprising:
a first chip protective layer on the first semiconductor chip, the first chip protective layer covering a sidewall of the first chip pad,
wherein the first insulation layer covers the first chip protection layer.

3. The semiconductor package according to claim 2, wherein
the first conductive connection pattern has a shape of a line extending in a horizontal direction on an upper surface of the first chip protective layer and the upper surface of the first chip pad and a shape of a line extending in a vertical direction on a sidewall of the first chip protective layer and the sidewall of the first semiconductor chip, and
the first conductive connection pattern is bent at an interface between the upper surface and the sidewall of the first chip protective layer.

4. The semiconductor package according to claim 1, wherein the first conductive connection pattern includes gold, silver or copper.

5. The semiconductor package according to claim 1, wherein the first insulation layer includes a thermosetting resin.

6. The semiconductor package according to claim 1, wherein the first insulation layer includes an inorganic insulation material.

7. The semiconductor package according to claim 1, further comprising:
a second semiconductor chip on the first insulation layer;
a second chip pad on the second semiconductor chip;
a second conductive connection pattern on an upper surface of the second chip pad, a sidewall of the second semiconductor chip, an upper surface and a sidewall of the first insulation layer, and an upper surface of a second substrate pad among the substrate pads; and
a second insulation layer on the package substrate, the second insulation layer covering the first insulation layer, the second semiconductor chip, the second chip pad, and the second conductive connection pattern.

8. The semiconductor package according to claim 7, further comprising:
a second chip protective layer on the second semiconductor chip, the second chip protective layer covering a sidewall of the second chip pad,
wherein the second insulation layer covers the second chip protection layer.

9. The semiconductor package according to claim 8, wherein
the second conductive connection pattern has a shape of a line extending in a horizontal direction on an upper surface of the second chip protective layer and the upper surface of the second chip pad, a shape of a line extending in a vertical direction on a sidewall of the second chip protective layer and the sidewall of the second semiconductor chip, a shape of a line extending in the horizontal direction on the upper surface of the first insulation layer, and a shape of a line extending in the vertical direction on the sidewall of the first insulation layer, and
the second conductive connection pattern is bent at an interface between the upper surface and the sidewall of the second chip protective layer, at an interface between the sidewall of the second semiconductor chip and the upper surface of the first insulation layer, and at an interface between the upper surface and the sidewall of the first insulation layer.

10. The semiconductor package according to claim 7, further comprising:
an adhesion layer between the upper surface of the first insulation layer and a lower surface of the second semiconductor chip.

11. The semiconductor package according to claim 7, further comprising:
a third semiconductor chip on the second insulation layer;
a third chip pad on the third semiconductor chip; and
a third conductive connection pattern on an upper surface of the third chip pad, a sidewall of the third semiconductor chip, an upper surface and a sidewall of the second insulation layer, and an upper surface of a third substrate pad among the substrate pads.

12. The semiconductor package according to claim 11, further comprising:
a third chip protective layer on the third semiconductor chip, the third chip protective layer covering a sidewall of the third chip pad,
wherein the third conductive connection pattern covers the third chip protection layer.

13. The semiconductor package according to claim 12, wherein
the third conductive connection pattern has a shape of a line extending in a horizontal direction on an upper surface of the third chip protective layer and the upper surface of the third chip pad, a shape of a line extending in a vertical direction on a sidewall of the third chip protective layer and the sidewall of the third semiconductor chip, a shape of a line extending in the horizontal direction on the upper surface of the second insulation layer, and a shape of a line extending in the vertical direction on the sidewall of the second insulation layer, and
the third conductive connection pattern is bent at an interface between the upper surface and the sidewall of the third chip protective layer, at an interface between the sidewall of the third semiconductor chip and the upper surface of the second insulation layer, and at an interface between the upper surface and the sidewall of the second insulation layer.

14. The semiconductor package according to claim 7, further comprising:
a third semiconductor chip on the second insulation layer;
a third chip pad on the third semiconductor chip;
a third chip protective layer on the third semiconductor chip, the third chip protective layer covering a sidewall of the third chip pad; and
a third conductive connection pattern on an upper surface and a sidewall of the third chip protective layer, a sidewall of the third semiconductor chip and an upper surface of the second insulation layer, the third conductive connection pattern extending through the second insulation layer and contacting the second conductive connection pattern.

15. A semiconductor package comprising:
a package substrate including substrate pads on an upper portion of the package substrate;
semiconductor chips stacked on the package substrate;
chip pads on the semiconductor chips, respectively; and
a conductive connection pattern on an upper surface of each of the chip pads, a sidewall of a corresponding one of the semiconductor chips, and a respective one of the substrate pads.

16. A semiconductor package comprising:
a package substrate including first, second, and third substrate pads on an upper portion of the package substrate;
a first semiconductor chip on the package substrate;
a first chip pad on the first semiconductor chip;
a first chip protective layer on the first semiconductor chip, the first chip protective layer covering a sidewall of the first chip pad;
a first conductive connection pattern on an upper surface of the first chip pad, an upper surface and a sidewall of the first chip protective layer, a sidewall of the first semiconductor chip, and an upper surface of a first substrate pad;
a first insulation layer on the package substrate, the first insulation layer covering the first semiconductor chip, the first chip pad, and the first conductive connection pattern;
a second semiconductor chip on the first insulation layer;
a second chip pad on the second semiconductor chip;
a second chip protective layer on the second semiconductor chip, the second chip protective layer covering a sidewall of the second chip pad;
a second conductive connection pattern on an upper surface of the second chip pad, an upper surface and a sidewall of the second chip protective layer, a sidewall of the second semiconductor chip, and an upper surface of a second substrate pad;
a second insulation layer on the package substrate, the second insulation layer covering the first insulation layer, the second semiconductor chip, the second chip pad, and the second conductive connection pattern;
a third semiconductor chip on the second insulation layer;
a third chip pad on the third semiconductor chip;
a third chip protective layer on the third semiconductor chip, the third chip protective layer covering a sidewall of the third chip pad;
a third conductive connection pattern on an upper surface of the third chip pad, an upper surface and a sidewall of the third chip protective layer, a sidewall of the third semiconductor chip, and an upper surface of a third substrate pad; and
a molding member on the package substrate, the molding member covering the second insulation layer, the third semiconductor chip, the third chip pad, the third chip protective layer and the third conductive connection pattern.

17. The semiconductor package according to claim 16, further comprising:
an adhesion layer between the package substrate and the first semiconductor chip.

18. The semiconductor package according to claim 16, further comprising:
an adhesion layer between the first insulation layer and the second semiconductor chip and between the second insulation layer and the third semiconductor chip.

19. The semiconductor package according to claim 16, wherein
each of the first and second insulation layers includes an inorganic insulation material, and
the molding member includes epoxy molding compound (EMC).

20. The semiconductor package according to claim 16, wherein each of the first to third conductive connection patterns includes a first portion extending in a horizontal direction and a second portion extending in a vertical direction.
